(19) United States
(12) Patent Application Publication
(10) Pub. No.: US 2026/0002257 A1
(43) Pub. Date: Jan. 1, 2026

(54) SUBSTRATE PROCESSING APPARATUS

(71) Applicant: SAMSUNG ELECTRONICS CO., LTD., Suwon-si (KR)

(72) Inventors: Jae Hoon KIM, Suwon-si (KR); Kyung Rim KIM, Suwon-si (KR); Dong Hee HAN, Suwon-si (KR)

(73) Assignee: SAMSUNG ELECTRONICS CO., LTD., Suwon-si (KR)

(21) Appl. No.: 19/016,657

(22) Filed: Jan. 10, 2025

(30) Foreign Application Priority Data
Jun. 27, 2024 (KR) 10-2024-008410

(51) Int. Cl. C23C 16/44; C23C 16/52; G01N 29/04

(52) U.S. Cl. CPC C23C 16/4402; C23C 16/52; G01N 29/043

(57) ABSTRACT

A substrate treating apparatus includes a pipe for providing a precursor and having a first zone and a second zone. A first heater provides heat to an inside of the pipe in the first zone, and a first ultrasonic sensor in the first zone generates a first ultrasonic wave directed to the inside of the pipe and receives a first reflected wave from the inside of the pipe. A second heater provides heat into the inside of the pipe in the second zone, and a second ultrasonic sensor in the second zone generates a second ultrasonic wave directed to the inside of the pipe and receives a second reflected wave from the inside of the pipe. A controller analyzes the first reflected wave and the second reflected wave to determine whether a contaminant has formed inside the pipe in the first zone or the second zone.

### CROSS-REFERENCE TO RELATED APPLICATION

This application claims priority from Korean Patent Application No. 10-2024-0084107 filed on Jun. 27, 2024 in the Korean Intellectual Property Office, and all the benefits accruing therefrom under 35 U.S.C. 119, the contents of which in its entirety are herein incorporated by reference.

### TECHNICAL FIELD

The present disclosure relates to a substrate processing apparatus.

### BACKGROUND

Among various steps of processing a substrate, a process of depositing a thin film on the substrate is performed in various ways. The thin film deposition process includes, for example, an atomic layer deposition (ALD) process or a chemical vapor deposition process (CVD).

Most of thin film deposition processes use a precursor. In this regard, a scheme for steadily supplying a constant amount of the precursor during the substrate processing process is used. In order to supply the constant amount of the precursor, it is important to detect and pre-prevent contaminants from occurring in a pipe through which the precursor is supplied.

### SUMMARY

A purpose to be achieved by the present disclosure is to provide a substrate treating apparatus that may easily detect and remove contaminants in a pipe.

The technical purposes of the present disclosure are not limited to the technical purposes as mentioned above, and other technical purposes not mentioned will be clearly understood by those skilled in the art from descriptions as set forth below.

According to an aspect of the present disclosure, there is provided a substrate treating apparatus comprising a pipe including a first zone and a second zone, and configured to provide a precursor, a first heater disposed to surround an outside of the pipe in the first zone and configured to provide heat to an inside of the pipe in the first zone, a first ultrasonic sensor disposed between the outside of the pipe and the first heater in the first zone, and configured to generate a first ultrasonic wave into the inside of the pipe in the first zone and to receive a first reflected wave as the first ultrasonic wave reflected from the inside of the pipe in the first zone, a second heater disposed to surround the outside of the pipe in the second zone and to provide heat into the inside of the pipe in the second zone, a second ultrasonic sensor disposed between the outside of the pipe and the second heater in the second zone, and configured to generate a second ultrasonic wave into the inside of the pipe in the second zone and to receive a second reflected wave as the second ultrasonic wave reflected from the inside of the pipe in the second zone, and a controller configured to: analyze the first reflected wave and determine whether a contaminant has formed inside the pipe in the first zone based on the analyzing result thereof, and analyze the second reflected wave and determine whether a contaminant has formed inside the pipe in the second zone based on the analyzing result thereof.

According to an aspect of the present disclosure, there is provided a substrate treating apparatus comprising a central supply tank for providing precursor; a pipe connected to the central supply tank and configured to deliver the precursor; a chamber connected to the central supply tank via the pipe and constructed to receive the precursor; and a controller, wherein the pipe includes a first zone and a second zone, wherein a first heater is disposed to surround an outside of the pipe in the first zone and is configured to provide heat into an inside of the pipe in the first zone, wherein a first ultrasonic sensor is disposed between the outside of the pipe and the first heater in the first zone and configured to generate a first ultrasonic wave into the inside of the pipe in the first zone and to receive a first reflected wave as the first ultrasonic wave reflected from the inside of the pipe in the first zone, wherein a first temperature sensor is disposed between the outside of the pipe and the first heater in the first zone and is configured to detect a temperature inside the pipe in the first zone, wherein a second heater is disposed to surround the outside of the pipe in the second zone and is configured to provide heat into the inside of the pipe in the second zone, wherein a second ultrasonic sensor is disposed between the outside of the pipe and the second heater in the second zone and is configured to generate a second ultrasonic wave into the inside of the pipe in the second zone and to receive a second reflected wave as the second ultrasonic wave reflected from the inside of the pipe in the second zone, wherein a second temperature sensor is disposed between the outside of the pipe and the second heater in the second zone and is configured to detect a temperature inside the pipe in the second zone, wherein the controller is configured to analyze the first reflected wave and determine whether a contaminant has formed inside the pipe in the first zone, based on the analyzing result thereof, wherein the controller is configured to analyze the second reflected wave and determine whether a contaminant has formed inside the pipe in the second zone, based on the analyzing result thereof.

According to an aspect of the present disclosure, there is provided a substrate treating apparatus comprising a central supply tank, a pipe connected to the central supply tank, and including a plurality of zones, wherein the pipe is configured to receive precursor in a gaseous state from the central supply tank and deliver the precursor, a chamber connected to the central supply tank through the pipe, and configured to receive the precursor and to perform an atomic layer deposition (ALD) process or a chemical vapor deposition (CVD) process using the precursor, and a controller configured to determine whether each of the zones of the pipe has been contaminated, wherein each heater surrounds an outside of the pipe in each of the zones and provides heat to an inside of the pipe in each zone, wherein each ultrasonic sensor is disposed between the outside of the pipe and each heater in each zone and is configured to generate an ultrasonic wave into the inside of the pipe in each zone and receive a reflected wave as the ultrasonic wave reflected from the inside of the pipe in each zone, wherein each temperature sensor is disposed between the outside of the pipe and the heater in each zone and is configured to detect a temperature inside the pipe in each zone, wherein the controller is configured to analyze the reflected wave corresponding to each zone and determine whether the contaminant has formed inside the pipe in each zone, based on the analyzing result, wherein the contaminant is generated via phase change of the precursor into a liquid state or a solid state.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail some embodiments thereof with reference to the attached drawings, in which:

FIG. 1 is an apparatus configuration diagram for illustrating a substrate treating apparatus according to some embodiments of the present disclosure.

FIG. 2 and FIG. 3 are enlarged views of a pipe in FIG. 1 to illustrate a structure of the pipe according to some embodiments of the present disclosure.

FIG. 4 and FIG. 5 are graphs showing a detection result of the ultrasonic sensor by way of example to describe a contaminant detection principle using the ultrasonic sensor according to some embodiments of the present disclosure.

FIG. 6 is an enlarged view of a portion of the pipe of FIG. 1 to describe the structure of the pipe according to some embodiments of the present disclosure.

FIG. 7 is an enlarged view of a portion of the pipe in FIG. 1 to describe the structure of the pipe according to some embodiments of the present disclosure.

FIG. 8 is an apparatus configuration diagram for illustrating a substrate treating apparatus according to some embodiments of the present disclosure.

FIG. 9 is an enlarged view of a portion of the pipe in FIG. 1 to describe a substrate treating apparatus according to some embodiments of the present disclosure.

FIG. 10 is an enlarged view of a portion of the pipe of FIG. 1 to describe the substrate treating apparatus according to some embodiments of the present disclosure.

FIG. 11 is an enlarged view of a portion of the pipe of FIG. 1 to describe a substrate treating apparatus according to some embodiments of the present disclosure.

FIG. 12 is a flowchart for illustrating a method for controlling a substrate treating apparatus according to some embodiments of the present disclosure.

### DETAILED DESCRIPTION

As used herein, although the terms first, second, etc. are used to describe various elements or components, these elements or components are not limited by these terms. These terms may be used to distinguish one element or component from another element or component. Therefore, it is to be appreciated that a description of first element or component may just as well be described as a second element or component within the technical concept of the present disclosure.

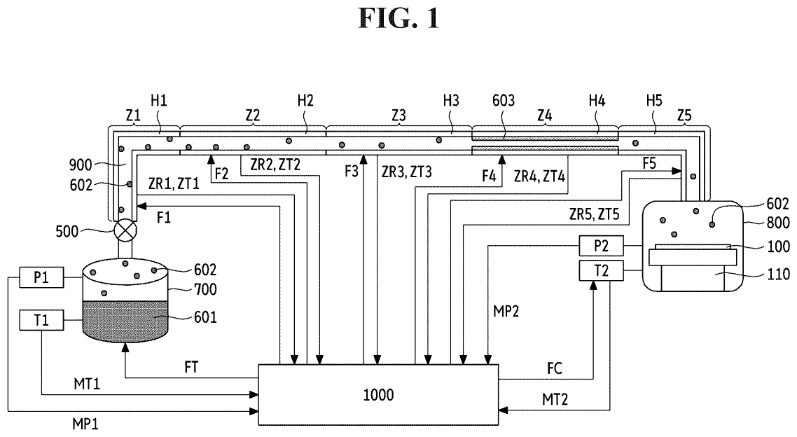

FIG. 1 is an apparatus configuration diagram for illustrating a substrate treating apparatus according to some embodiments of the present disclosure.

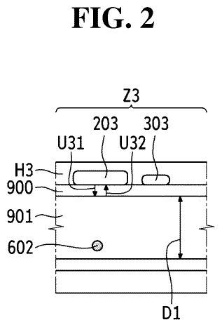

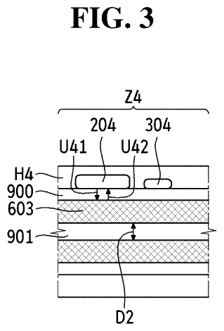

FIG. 2 and FIG. 3 are enlarged views of a pipe in FIG. 1 to illustrate a structure of the pipe according to some embodiments of the present disclosure. For reference, FIG. 2 is an enlarged view of a zone where a contaminant 603 has not formed, and FIG. 3 is an enlarged view of a zone where the contaminant 603 has formed.

Referring to FIGS. 1 to 3, the substrate treating apparatus according to some embodiments of the present disclosure may include a central supply tank 700, a tank pressure gauge P1, a tank temperature sensor T1, a valve 500, a pipe 900, a chamber 800, a chamber pressure gauge P2, a chamber temperature sensor T2, and a controller 1000.

A precursor may be stored in the central supply tank 700. The precursor provided in the central supply tank 700 may be in a solid state. However, embodiments of the present disclosure are not limited thereto. The precursor provided in the central supply tank 700 may include, for example, molybdenum tetrachloride (MoCl₄) and/or molybdenum dioxide chloride (MoO₂Cl₂). However, embodiments of the present disclosure are not limited thereto.

The tank temperature sensor T1 may detect a temperature inside the central supply tank 700. The tank temperature sensor T1 may be, for example, a thermocouple. The tank pressure gauge P1 may detect a pressure inside the central supply tank 700. The tank pressure gauge P1 may be, for example, a manometer. Each of the tank temperature sensor T1 and the tank pressure gauge P1 may transmit information about the temperature and the pressure, respectively, of the central supply tank 700 to the controller 1000.

For example, the tank temperature sensor T1 and the tank pressure gauge P1 may provide information about the temperature and pressure inside the central supply tank 700 to the controller 1000 in order to control phase change of precursor 601 in a first state into precursor 602 in a second state inside the central supply tank 700.

The central supply tank 700 may be connected to the pipe 900. The valve 500 may be disposed between the central supply tank 700 and the pipe 900. The valve 500 may provide the precursor from the central supply tank 700 to an inside of the pipe 900, or may stop providing the precursor thereto.

The pipe 900 may connect the central supply tank 700 and the chamber 800 to each other. The precursor 601 in the first state provided in the central supply tank 700 may be provided into the pipe 900 as the precursor 602 in the second state having a phase different from a phase of the precursor 601. The precursor 601 in the first state may be provided in the central supply tank 700, and heat may be applied to the central supply tank 700 so that the precursor 601 in the first state changes into the precursor 602 in the second state, and then, the precursor 602 in the second state may be provided into the pipe 900.

For example, when a solid state precursor is provided in the central supply tank 700, heat may be applied to the central supply tank 700 to sublimate the precursor into a gas. In this manner, the sublimated precursor may be provided into the pipe 900. In another example, when a solid state precursor is provided in the central supply tank 700, heat may be applied to the central supply tank 700 to melt the precursor into a liquid. The melted precursor may be provided into the pipe 900.

The second-state precursor 602 may be supplied into the pipe 900. The second-state precursor 602 may be transferred from the central supply tank 700 to the chamber 800 as described below through the pipe 900.

The precursor 602 in the second state may be delivered to the chamber 800 through an inner space of the pipe 900 as a hollow portion 901 of the pipe 900. Depending on a diameter D1 of the hollow portion 901 of the pipe 900, an amount of the precursor 602 in the second state that may be delivered into the pipe 900 may vary. For example, as shown in FIG. 2, when the contaminant 603 has not formed inside the pipe 900, the diameter D1 of the hollow portion 901 through which the precursor 602 in the second state may be provided may be the same as an inner diameter of the pipe 900.

In another example, when the contaminant 603 has formed inside the pipe 900, a diameter D2 of the hollow portion 901 of the pipe 900 may be reduced due to the contaminant 603. The diameter D2 of the hollow portion 901 of the pipe 900 where the contaminant 603 has formed may be smaller than the diameter D1 of the hollow portion 901 of the pipe 900 where the contaminant 603 has not formed.

The contaminant 603 may be formed via phase change of the precursor 602 in the second state. For example, when a precursor in a gaseous state is provided into the pipe 900, some of the precursor in the gaseous state may transition into a solid state, thereby forming the contaminant 603 inside the pipe 900. In other words, the precursor 602 in the second state may not be properly supplied to the chamber 800 due to the contaminant 603.

The pipe 900 may include a plurality of zones. For example, the pipe 900 may include a first zone Z1, a second zone Z2, a third zone Z3, a fourth zone Z4, and a fifth zone Z5 arranged in this order. Although the first to fifth zones Z1 to Z5 are illustrated in FIG. 1, the present disclosure is not limited thereto. In other words, the pipe 900 may include any number of zones.

For example, each of the zones Z1 to Z5 may have a length of about 10 cm to 100 cm. However, embodiments of the present disclosure are not limited thereto. When the length of each of the zones Z1 to Z5 is smaller than 10 cm, the pipe 900 may be divided into too many zones. This may require a large number of heaters to be installed and controlled for zone-specific control of the pipe 900, thereby decreasing process efficiency. When the length of each of the zones Z1 to Z5 is larger than 100 cm, the pipe 900 may be divided into too few zones, making it difficult to precisely determine a contamination amount inside the pipe 900, thereby reducing process efficiency.

When the pipe 900 is not divided into different zones, it may be difficult to identify which portion of the pipe 900 is contaminated. To prevent this situation, the pipe 900 may be divided into several zones to identify a zone where the contaminant 603 has formed. Accordingly, the contaminant 603 formed in the pipe 900 may be identified and removed more easily. A heater may be disposed on an outside of the pipe 900 in each zone. The heater may be disposed to surround the outside of the pipe 900 in each zone. For example, a first heater H1 may be disposed to entirely surround the outside of the pipe 900 in the first zone Z1. In another example, a fourth heater H4 may be disposed to entirely surround the outside of the pipe 900 in the fourth zone Z4.

Each heater may provide heat to the inside of the pipe 900 in each zone, thereby heating the inside of the pipe 900 in each zone. For example, the first heater H1 may provide heat to the inside of the pipe 900 in the first zone Z1. As another example, the fourth heater H4 may provide heat to the inside of the pipe 900 in the fourth zone Z4.

An ultrasonic sensor may be disposed on the outside of the pipe 900 in each zone. The ultrasonic sensor may be disposed between the outside of the pipe 900 and the heater in each zone. The ultrasonic sensor in each zone may generate an ultrasonic wave toward the inside of the pipe 900 in each zone. The ultrasonic wave generated from the ultrasonic sensor may impinge on an inner wall of the pipe 900 and be reflected therefrom. The reflected wave generated as the reflected ultrasonic wave may be detected by the ultrasonic sensor. The ultrasonic sensor may transmit information about the detected reflected wave to the controller 1000 as described later.

For example, with reference to FIG. 2, a third ultrasonic sensor 203 disposed in the third zone Z3 may generate a third ultrasonic wave U31 into the inside of the pipe 900 in the third zone Z3. The third ultrasonic wave U31 generated from the third ultrasonic sensor 203 may generate a third reflected wave U32. The third ultrasonic sensor 203 may detect the third reflected wave U32 generated as a reflected third ultrasonic wave U31. The third ultrasonic sensor 203 may transmit information about the third reflected wave U32 to the controller 1000.

For example, with reference to FIG. 3, a fourth ultrasonic sensor 204 disposed in the fourth zone Z4 may generate a fourth ultrasonic wave U41 into the inside of the pipe 900 in the fourth zone Z4. The fourth ultrasonic wave U41 generated from the fourth ultrasonic sensor 204 may generate a fourth reflected wave U42. The fourth ultrasonic sensor 204 may detect a fourth reflected wave U42 generated as a reflected fourth ultrasonic wave U41. The fourth ultrasonic sensor 204 may transmit information about the fourth reflected wave U42 to the controller 1000.

A temperature sensor may be disposed on the outside of the pipe 900 in each zone. Specifically, the temperature sensor may be disposed between the outside of the pipe 900 and the heater in each zone. The temperature sensor may detect the temperature inside the pipe 900 in each zone. The temperature sensor in each zone may detect the temperature inside the pipe 900 in each zone and transmit the detected temperature to the controller 1000. For example, the temperature sensor may be a thermocouple. However, an embodiment of the present disclosure is not limited thereto.

For example, with reference to FIG. 2, a third temperature sensor 303 disposed in the third zone Z3 may detect the temperature inside the pipe 900 in the third zone Z3. Information about the temperature inside the pipe 900 in the third zone Z3 detected by the third temperature sensor 303 may be transmitted to the controller 1000.

For example, with reference to FIG. 3, a fourth temperature sensor 304 disposed in the fourth zone Z4 may detect the temperature inside the pipe 900 in the fourth zone Z4. Information about the temperature inside the pipe 900 in the fourth zone Z4 detected by the fourth temperature sensor 304 may be transmitted to the controller 1000.

For example, with reference to FIG. 2, the third heater H3, the third ultrasonic sensor 203, and the third temperature sensor 303 may be disposed on the outside of the pipe 900 in the third zone Z3. The third heater H3 may be disposed to surround the outside of the pipe 900 in the third zone Z3. The third heater H3 may provide heat to the inside of the pipe 900 in the third zone Z3. The third ultrasonic sensor 203 may be disposed between the outside of the pipe 900 and the third heater H3 in the third zone Z3. The third ultrasonic sensor 203 may generate the third ultrasonic wave U31 and detect the third reflected wave U32 and transmit the detection result to the controller 1000. The third temperature sensor 303 may be disposed between the outside of the pipe 900 and the third heater H3 in the third zone Z3. The third temperature sensor 303 may detect the temperature inside the pipe 900 in the third zone Z3.

For example, with reference to FIG. 3, the fourth heater H4, the fourth ultrasonic sensor 204, and the fourth temperature sensor 304 may be disposed on the outside of the pipe 900 in the fourth zone Z4. The fourth heater H4 may be disposed to surround the outside of the pipe 900 in the fourth zone Z4. The fourth heater H4 may provide heat inside the pipe 900 in the fourth zone Z4. The fourth ultrasonic sensor 204 may be disposed between the outside of the pipe 900 and the fourth heater H4 in the fourth zone Z4. The fourth ultrasonic sensor 204 may generate the fourth ultrasonic wave U41 and detect the fourth reflected wave U42 and transmit the detection result to the controller 1000. The fourth temperature sensor 304 may be disposed between the outside of the pipe 900 and the fourth heater H4 in the fourth zone Z4. The fourth temperature sensor 304 may detect the temperature inside the pipe 900 in the fourth zone Z4.

Returning to FIG. 1, the chamber 800 may accommodate therein a substrate support 110 and a substrate 100. The substrate 100 may be fixed on the substrate support 110. The chamber 800 may receive the precursor 602 in the second state through the pipe 900. A process may be performed in the chamber 800 using the received precursor 602 in the second state. A process of depositing a thin film on the substrate 100 may be performed in the chamber 800. For example, an atomic layer deposition process (ALD) or a chemical vapor deposition process (CVD) may be performed in the chamber 800. However, embodiments of the present disclosure are not limited thereto.

A chamber temperature sensor T2 may detect the temperature inside the chamber 800. The chamber temperature sensor T2 may be, for example, a thermocouple. A chamber pressure gauge P2 may detect a pressure inside the chamber 700. The chamber pressure gauge P2 may be, for example, a manometer. Each of the chamber temperature sensor T2 and the chamber pressure gauge P2 may transmit information about each of the temperature and the pressure of the chamber 800 to the controller 1000.

The controller 1000 may receive information MP1 about the internal pressure of the central supply tank 700 from the tank pressure gauge P1. The controller 1000 may receive information MT1 about the internal temperature of the central supply tank 700 from the tank temperature sensor T1. The controller 1000 may provide a feedback FT to a pressure controller (not shown) and a temperature controller (not shown) of the central supply tank 700 to control the pressure and the temperature inside the central supply tank 700.

The controller 1000 may receive information MP2 about the internal pressure of the chamber 800 from the chamber pressure gauge P2. The controller 1000 may receive information MT2 about the internal temperature of the chamber 800 from the chamber temperature sensor T2. The controller 1000 may provide a feedback FC to a pressure controller (not shown) and a temperature controller (not shown) of the chamber 800 to control the pressure and the temperature inside the chamber 800.

The controller 1000 may receive information about the reflected wave in each zone from the ultrasonic sensor in each zone. For example, the controller 1000 may receive information ZR3 about the third reflected wave U32 in the third zone Z3 recognized by the third ultrasonic sensor 203.

The controller 1000 may receive information about the temperature in each zone from the temperature sensor in each zone. For example, the controller 1000 may receive information ZT3 about the temperature inside the pipe 900 in the third zone Z3 recognized by the third temperature sensor 303. The controller 1000 may control the heater in each zone of the pipe 900 to remove the contaminant 603 formed inside the pipe 900 based on the information about the reflected wave in each zone. For example, when it is determined that the contaminant 603 has formed in the fourth zone Z4, the controller 1000 may control the temperature inside the pipe 900 in the fourth zone Z4 based on a feedback F4 that controls the fourth heater H4.

For example, the precursor 601 in the first state provided in the central supply tank 700 is in a solid state and the precursor 602 in the second state provided into the pipe 900 is in a gaseous state. In this case, when it is determined that the contaminant 603 has formed in the fourth zone Z4, the controller 1000 may control the fourth heater H4 to adjust the temperature inside the pipe 900 in the fourth zone Z4 to a sublimation point of the precursor.

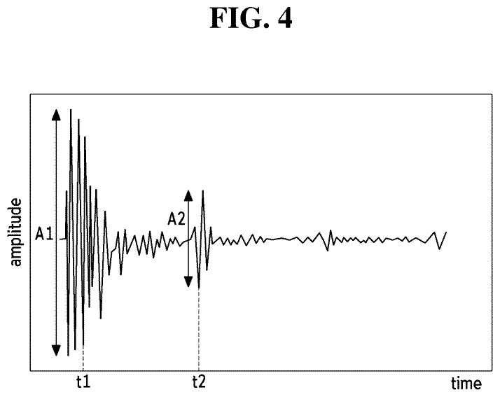

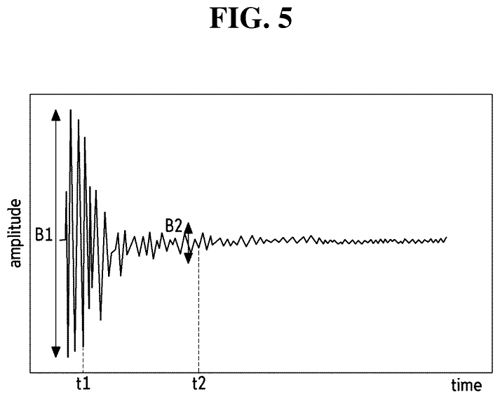

FIG. 4 and FIG. 5 are graphs showing a detection result of the ultrasonic sensor by way of example to describe a contaminant detection principle using the ultrasonic sensor according to some embodiments of the present disclosure. For reference, FIG. 4 is a graph showing the detection result of the ultrasonic sensor in the fourth zone Z4 when the contaminant (603 in FIG. 3) is not formed, by way of example. FIG. 5 is a graph showing the detection result of the ultrasonic sensor in the fourth zone Z4 when the contaminant (603 in FIG. 3) is formed, by way of example.

Referring to FIG. 4, the fourth ultrasonic wave (U41 in FIG. 3) may be generated toward the inside of the pipe (900 in FIG. 3) in the fourth zone (Z4 in FIG. 3). For example, the fourth ultrasonic wave U41 may be generated into the pipe 900 at a first time t1. The fourth reflected wave (U42 in FIG. 3) as the reflected fourth ultrasonic wave U41 is detected at a second time t2. For example, the second time t2 means a time duration for which the fourth ultrasonic wave U41 collides with the inside of the pipe 900 in the fourth zone Z4 and is reflected therefrom, and the fourth reflected wave U42 as the reflected fourth ultrasonic wave U41 is detected by the fourth ultrasonic sensor (204 in FIG. 3). For example, the second time t2 may be, but is not limited to, about 0.4 microseconds (s) after the first time t1.

The fourth ultrasonic wave U41 has a first amplitude A1, and the fourth reflected wave U42 has a second amplitude A2. The second amplitude A2 of the fourth reflected wave U42 is smaller than the first amplitude A1 of the fourth ultrasonic wave U41. For example, the second amplitude A2 of the fourth reflected wave U42 may have an amplitude of about 50% of the first amplitude A1 of the fourth ultrasonic wave U41. However, embodiments of the present disclosure are not limited thereto. A ratio of the amplitudes of the fourth reflected wave U42 and the fourth ultrasonic wave U41 as detected by the fourth ultrasonic sensor 204 may vary depending on a material, a thickness, etc. of the pipe 900 in the fourth zone Z4.

Referring to FIG. 5, the fourth ultrasonic wave (U41 in FIG. 3) may be generated into the inside of the pipe (900 in FIG. 3) in the fourth zone (Z4 in FIG. 3). For example, the fourth ultrasonic wave U41 may be generated into the inside of the pipe 900 at the first time t1. The fourth reflected wave (U42 in FIG. 3) as the reflected fourth ultrasonic wave U41 is detected at the second time t2. For example, the second time t2 means a time duration for which the fourth ultrasonic wave U41 is reflected from the inside of the pipe 900 in the fourth zone Z4, and the fourth reflected wave U42 as the reflected fourth ultrasonic wave U41 is detected by the fourth ultrasonic sensor (204 in FIG. 3). For example, the second time t2 may be about 0.4 microseconds after the first time t1. However, embodiments of the present disclosure are not limited thereto.

The fourth ultrasonic wave U41 may have a first amplitude B1, and the fourth reflected wave U42 may have a second amplitude B2. The second amplitude B2 of the fourth reflected wave U42 may be smaller than the first amplitude B1 of the fourth ultrasonic wave U41. For example, the second amplitude B2 of the fourth reflected wave U42 may have an amplitude of about 10% of the first amplitude B1 of the fourth ultrasonic wave U41. However, an embodiment of the present disclosure is not limited thereto. A ratio of the amplitudes of the fourth reflected wave U42 and the fourth ultrasonic wave U41 detected by the fourth ultrasonic sensor 204 may vary depending on a condition such as the material and thickness of the pipe 900 in the fourth zone Z4.

The amplitude A2 of the fourth reflected wave U42 detected when the contaminant 603 has not formed may be different from the amplitude B2 of the fourth reflected wave U42 detected when the contaminant 603 has formed. The amplitude B2 of the fourth reflected wave U42 detected when the contaminant 603 has formed may be smaller than the amplitude A2 of the fourth reflected wave U42 detected when the contaminant 603 has not formed. For example, the amplitude B2 of the fourth reflected wave U42 detected when the contaminant 603 has formed may be about 20% or smaller of the amplitude A2 of the fourth reflected wave U42 detected when the contaminant 603 has not formed.

This difference in the amplitude magnitude may be caused due to the contaminant 603. The ultrasonic wave generated into the inside of the pipe 900 in the zone where the contaminant 603 has formed may be partially absorbed by the contaminant 603. Accordingly, the amplitude B2 of the fourth reflected wave U42 detected when the contaminant 603 has formed may be smaller than the amplitude A2 of the fourth reflected wave U42 detected when the contaminant 603 has not formed.

For reference, the first time t1 and the second time t2 disclosed in FIG. 4 may be the same as the first time t1 and the second time t2 disclosed in FIG. 5, respectively. However, embodiments of the present disclosure are not limited thereto. In another example, the first time t1 and the second time t2 disclosed in FIG. 4 may be different from the first time t1 and the second time t2 disclosed in FIG. 5, respectively.

The controller 1000 may receive information on the amplitude of the reflected wave and may determine whether the contaminant 603 has formed in each zone, based on the information. The controller 1000 may control the heater of the zone where the contaminant 603 is determined to have been formed to control the temperature inside the pipe 900 in the zone in order to remove the contaminant 603 therefrom. For example, when the contaminant 603 has formed, information about the detected fourth reflected wave U42 in the zone is provided to the controller 1000. When the controller 1000 determines that the contamination has formed in the fourth zone Z4, the controller 100 may control an operation of the fourth heater H4 to adjust the temperature inside the pipe 900 in the fourth zone Z4. For example, the controller 1000 may control the temperature inside the pipe 900 in the fourth zone Z4 to the sublimation point of the precursor.

For example, it is assumed that the precursor 601 in the first state is in a solid state, the precursor 602 in the second state is in a gas state, and the contaminant 603 is determined to have been formed in the fourth zone Z4. The precursor is molybdenum dioxide chloride. In this case, in order to remove the contaminant 603 formed from molybdenum dioxide chloride, the controller 1000 may control the fourth heater H4 to increase the temperature inside the pipe 900 in the fourth zone Z4 to about 190° C. as the sublimation point of molybdenum dioxide chloride.

For example, the temperature inside the pipe 900 may be in a range of about 50° C. inclusive to 200° C. inclusive. When the temperature inside the pipe 900 is lower than about 50° C., the precursor 602 in the second state may sublimate into a solid, thereby generating the contaminant 603 inside the pipe 900, such that the pipe becomes clogged. On the other hand, when the temperature inside the pipe 900 is in a range of about 200° C. or higher, the pipe 900 may be corroded. Therefore, the temperature inside the pipe 900 may be maintained in a range of about 50° C. inclusive to 200° C. inclusive.

The controller 1000 may determine the formation tendency of the contaminant 603 in the zones based on a collection of the information provided from the ultrasonic sensors in the zones. In other words, the controller 1000 may identify the zone in which the contaminant 603 is generated in a larger amount, or the zone in which the contaminant 603 is generated in a smaller amount. Based on the determining result of the formation tendency of the contaminant 603, the controller 1000 may determine the zone in which the heater should be controlled first to control the temperature inside the pipe 900.

For example, the contaminant 603 may be formed in the largest amount inside the pipe 900 in the fifth zone Z5 among the third zone Z3, the fourth zone Z4, and the fifth zone Z5 arranged in this order. In this case, an amplitude of a fifth reflected wave (not shown) detected by a fifth ultrasonic sensor (not shown) may be the smallest among the amplitudes of the third reflected wave U32, the fourth reflected wave U42, and the fifth reflected wave (not shown). In this case, the controller 1000 determines that the contaminant 603 has formed in the largest amount inside the pipe 900 in the fifth zone Z5, and first controls a fifth heater (not shown) to remove the contaminant 603 inside the pipe in the fifth zone Z5. In this manner, the controller 1000 may determine the tendency of the formation of the contaminant 603 in the zones based on a comparing result of the amplitudes of the reflected waves in the zones with each other.

Based on the analysis result of the reflected wave received from the ultrasonic sensor in each zone, the controller 1000 may control the operation of the heater in each zone. The controller 1000 may infer whether the pipe 900 in each zone is blocked with the contaminant 603 and prevent the pipe from being entirely blocked. In other words, the controller may determine the tendency of the formation of the contaminant 603, and may compare the contamination levels in the zones with each other, and accordingly, more efficiently cope with the blockage of the pipe 900 based on the comparison.

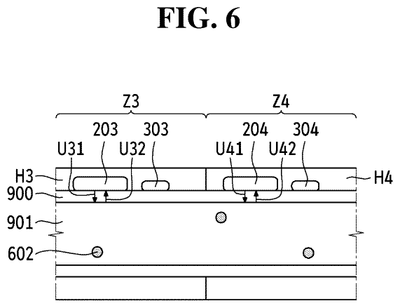

FIG. 6 is an enlarged view of a portion of the pipe of FIG. 1 to describe the structure of the pipe according to some embodiments. For reference, FIG. 6 is an enlarged view of the third zone Z3 and the fourth zone Z4 of FIG. 1.

Referring to FIG. 6, the heaters respectively disposed in the zones may be in contact with each other. For example, as shown in FIG. 6, the third heater H3 disposed in the third zone Z3 and the fourth heater H4 disposed in the fourth zone Z4 may be in contact with each other. However, the present disclosure is not limited thereto.

In another example, a spacing may be defined between the third heater H3 disposed in the third zone Z3 and the fourth heater H4 disposed in the fourth zone Z4. A size of the spacing may not be limited to a specific value. However, in one example, the spacing between the third heater H3 disposed in the third zone Z3 and the fourth heater H4 disposed in the fourth zone Z4 may be in a range of about 1 cm inclusive to 5 cm inclusive.

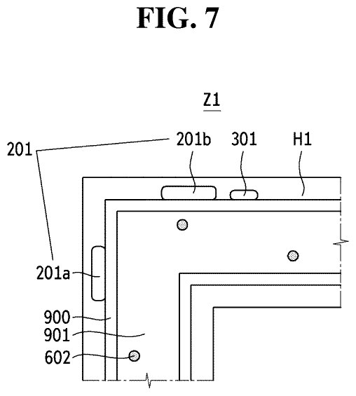

FIG. 7 is an enlarged view of a portion of the pipe in FIG. 1 to describe the structure of the pipe according to some embodiments of the present disclosure. For reference, FIG. 7 is an enlarged view of the first zone Z1 in FIG. 1.

Referring to FIG. 7, the pipe 900 may include a bent shape. In this case, the heater may surround the pipe 900. For example, when the first zone Z1 includes a bent shape, the first heater H1 may surround the outside of the pipe 900 in the bent first zone Z1. In other words, the first heater H1 may also include a bent shape.

A plurality of ultrasonic sensors may be included in one zone of the pipe 900. For example, a plurality of first ultrasonic sensors 201 may be disposed in the first zone Z1. In FIG. 7, two first ultrasonic sensors 201a and 201b are illustrated. However, the present disclosure is not limited thereto. In another example, three or more ultrasonic sensors 201 may be disposed in the first zone Z1.

In the pipe 900 including the bent shape, even when the contaminant (603 in FIG. 3) is formed due to the bent portion, the contaminant therein may not be properly detected. In this case, the plurality of ultrasonic sensors are disposed therein to determine whether the contaminant 603 has formed therein more precisely.

In FIG. 7, one first temperature sensor 301 is illustrated. However, the present disclosure embodiment is not limited thereto. In another example, two or more first temperature sensors 301 may be disposed in the first zone Z1.

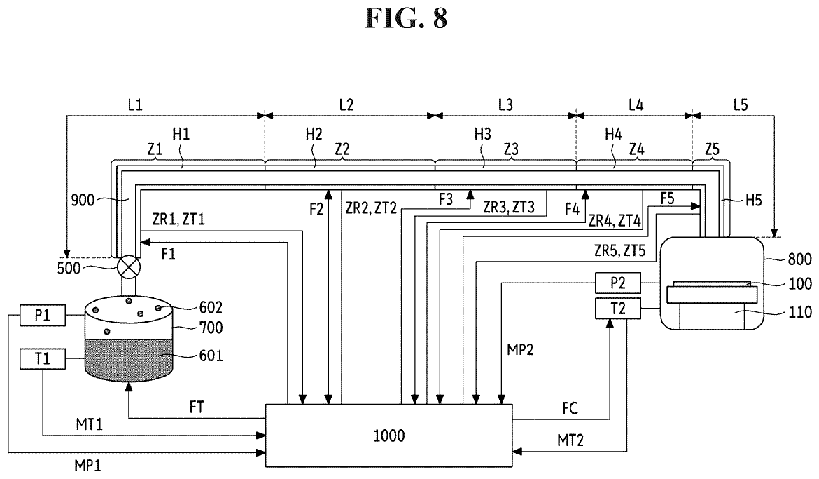

FIG. 8 is an apparatus configuration diagram for illustrating a substrate treating apparatus according to some embodiments of the present disclosure. For convenience of description, differences of FIG. 8 from FIGS. 1 to 7 will be mainly described. For reference, FIG. 8 is a diagram showing a state in which the valve 500 is closed and the precursor 602 in the second state is not provided into the pipe 900.

Referring to FIG. 8, lengths of the zones may be different from each other. For example, the closer the zone is positioned to the chamber 800, the smaller the length thereof may be. For example, the first zone Z1 may have a first length L1. The second zone Z2 may have a second length L2. The third zone Z3 may have a third length L3. The first length L1 may be larger than the second length L2. The second length L2 may be larger than the third length L3. In other words, the second length L2 may be larger than the third length L3 and smaller than the first length L1.

For example, the first length L1 of the first zone Z1 may be 10 cm, the second length L2 of the second zone Z2 may be 15 cm, and the third length L3 of the third zone Z3 may be 20 cm. However, embodiments of the present disclosure are not limited thereto. In another example, the length of the shortest zone among the zones may be 10 cm, and the length of the longest zone among the zones may be 100 cm.

As the zone is closer to the central supply tank 700, the precursor 602 in the second state is more easily provided to the zone without the phase change. On the other hand, as the zone is closer to the chamber 800, the contaminant (603 in FIG. 3) is more easily formed from the precursor 602 in the second state in the zone. As the zone gets closer to the chamber 800, the length of the zone becomes smaller. In this case, as the zone is closer to the chamber 800, the controller 1000 may determine whether the contaminant (603 in FIG. 3) has formed in the zone more precisely, and thus the temperature in the zone may be easily controlled, so that the contaminant 603 may be easily removed from the zone.

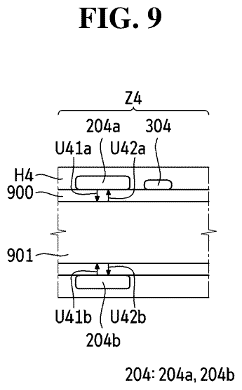

FIG. 9 is an enlarged view of a portion of the pipe in FIG. 1 to describe a substrate treating apparatus according to some embodiments of the present disclosure. For reference, FIG. 9 is an enlarged view of the fourth zone Z4 in FIG. 1. For convenience of description, differences of FIG. 9 from FIGS. 1 to 3 will be mainly described.

Referring to FIG. 9, the fourth heater H4, a plurality of fourth ultrasonic sensors 204, and the fourth temperature sensor 304 may be disposed on the outside of the pipe 900 in the fourth zone Z4. The fourth heater H4 may surround the outside of the pipe 900 in the fourth zone Z4. The fourth heater H4 may provide heat to the inside of the pipe 900 in the fourth zone Z4.

The plurality of fourth ultrasonic sensors 204 may be disposed between the outside of the pipe 900 Z4 and the fourth heater H4 in the fourth zone. The fourth ultrasonic sensors 204 may include a sixth ultrasonic sensor 204a and a seventh ultrasonic sensor 204b. The sixth ultrasonic sensor 204a may generate a sixth ultrasonic wave U41a and detect a sixth reflected wave U42a and transmit the detection result to the controller 1000. The seventh ultrasonic sensor 204b may generate a seventh ultrasonic wave U41b and detect a seventh reflected wave U42b and transmit the detection result to the controller 1000.

The fourth temperature sensor 304 may be disposed between the outside of the pipe 900 and the fourth heater H4 in the fourth zone Z4. The fourth temperature sensor 304 may detect the temperature inside the pipe 900 of the fourth zone Z4. In the case where the plurality of fourth ultrasonic sensors 204 are disposed in the fourth zone Z4, the formation of the contaminant 603 may be determined more precisely than in the case where one ultrasonic sensor is disposed in the fourth zone Z4. For example, in the case where the contaminant 603 has formed at one side in the diameter direction of the fourth zone Z4 in the inside of the pipe 900 and no contaminant 603 (or less contaminant) has formed at the other side in the diameter direction thereof in the inside of the pipe 900, the formation of the contaminant 603 may be determined more precisely because the plurality of ultrasonic sensors 204 are disposed therein.

FIG. 9 illustrates a case where two fourth ultrasonic sensors 204 are disposed on the outside of the pipe 900 in the fourth zone Z4. However, the present disclosure is not limited thereto. In another example, three or more fourth ultrasonic sensors 204 may be disposed in the fourth zone Z4. This may also be applied to each of the other zones of the pipe 900.

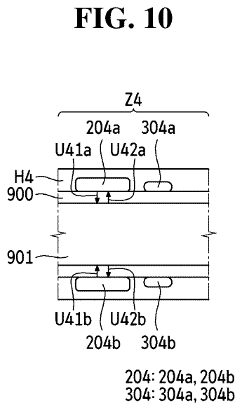

FIG. 10 is an enlarged view of a portion of the pipe of FIG. 1 to describe the substrate treating apparatus according to some embodiments of the present disclosure. For reference, FIG. 10 is an enlarged view of the fourth zone Z4 of FIG. 1. For convenience of description, differences of FIG. 10 from FIG. 9 will be mainly described.

Referring to FIG. 10, the fourth heater H4, the plurality of fourth ultrasonic sensors 204, and a plurality of fourth temperature sensors 304 may be disposed on the outside of the pipe 900 in the fourth zone Z4. The plurality of fourth temperature sensors 304 may be disposed between the outside of the pipe 900 and the fourth heater H4 in the fourth zone Z4. The plurality of fourth temperature sensors 304 may include a sixth temperature sensor 304a and a seventh temperature sensor 304b. The sixth temperature sensor 304a and the seventh temperature sensor 304b may detect the temperature inside the pipe 900 in the fourth zone Z4.

In FIG. 10, a case where two fourth ultrasonic sensors 204 are disposed on the outside of the pipe 900 in the fourth zone Z4 is illustrated. However, the present disclosure is not limited thereto. In another example, three or more fourth ultrasonic sensors 204 may be disposed on the outside of the pipe 900 in the fourth zone Z4. This may be applied to each of the other zones of the pipe 900.

In FIG. 10, a case where two fourth temperature sensors 304 are disposed on the outside of the pipe 900 in the fourth zone Z4 is illustrated. However, the present disclosure is not limited thereto. In another example, three or more fourth temperature sensors 304 may be disposed on the outside of the pipe 900 in the fourth zone Z4. This may also be applied to each of the other zones of the pipe 900.

In FIG. 10, two fourth ultrasonic sensors 204 and two fourth temperature sensors 304 are disposed on the outside of the pipe 900 in the fourth zone Z4. However, the present disclosure is not limited thereto. In another example, the number of ultrasonic sensors and the number of temperature sensors disposed in one zone may be different from each other.

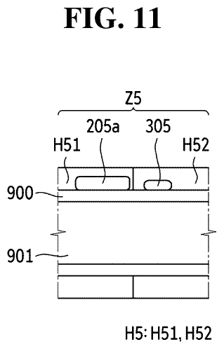

FIG. 11 is an enlarged view of a portion of the pipe of FIG. 1 to describe a substrate treating apparatus according to some embodiments of the present disclosure. For reference, FIG. 11 is an enlarged view of the fifth zone Z5 of FIG. 1. For convenience of description, differences of FIG. 11 from FIGS. 1 to 3 will be mainly described.

Referring to FIG. 11, the plurality of fifth heaters H5, the fifth ultrasonic sensor 205a, and the fifth temperature sensor 305 may be disposed on the outside of the pipe 900 in the fifth zone Z5. The plurality of fifth heaters H5 may include a sixth heater H51 and a seventh heater H52. Each of the sixth heater H51 and the seventh heater H52 may be disposed to surround the outside of the pipe 900 in the fifth zone Z5. The sixth heater H51 and the seventh heater H52 may provide heat to the inside of the pipe 900 in the fifth zone Z5.

In the case where the plurality of fifth heaters H5 are disposed in the fifth zone Z5, the temperature inside the pipe in the fifth zone Z5 may be controlled more precisely than in the case where one fifth heater H5 is disposed in the fifth zone Z5.

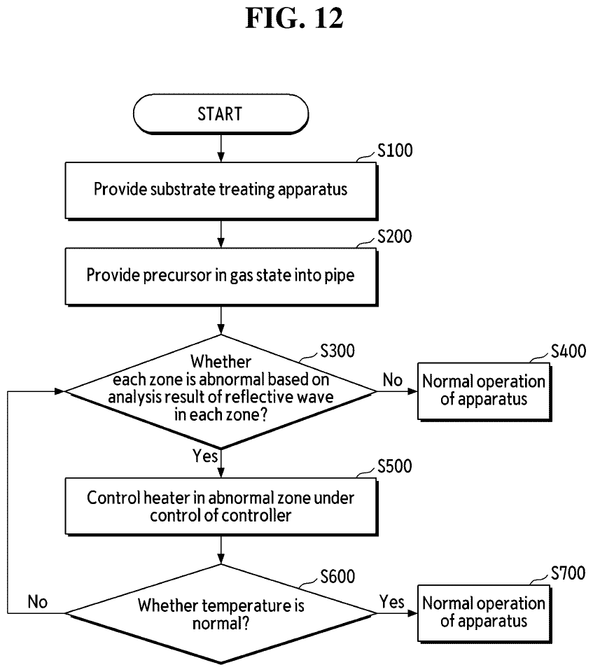

FIG. 12 is a flowchart for illustrating a method for controlling a substrate treating apparatus according to some embodiments of the present disclosure. Hereinafter, for convenience of description, the method for controlling the substrate treating apparatus as illustrated in FIG. 1 to FIG. 6 is described.

Referring to FIG. 12, the substrate treating apparatus is provided in S100.

Specifically, the substrate treating apparatus may include the central supply tank 700 of FIG. 1, the valve 500 of FIG. 1, the chamber 800 of FIG. 1, the pipe 900 of FIG. 1, and the controller 1000 of FIG. 1.

The precursor may be provided into the central supply tank 700. The first-state precursor 601 of FIG. 1 provided into the central supply tank 700 may change into the second-state precursor 602 of FIG. 1 having the different material phase from that of the first-state precursor 601 under the heat applied to the central supply tank 700.

Subsequently, when the valve 500 is opened, the second-state precursor 602 is provided from the central supply tank 700 to the pipe 900 in S200. For example, the second-state precursor 602 may be in a gaseous state.

Next, the amplitude of the reflected wave detected from the ultrasonic sensor in each of the zone may be analyzed, and an abnormal zone may be determined based on the analysis result S300. Hereinafter, the zone where the contaminant 630 is expected to have been formed is referred to as the abnormal zone.

Using the ultrasonic sensor in each zone, the ultrasonic wave is generated, and the reflected wave as the reflected ultrasonic wave is analyzed, and information on a waveform thereof may be provided to the controller 1000. The controller 1000 analyzes the reflected wave in each zone and finds the zone where the contaminant 603 is expected to have occurred.

When no abnormal zone is found, the apparatus operates normally in S400. For example, the heater disposed in each zone is not adjusted and operates as usual.

When the abnormal zone is found, the heater disposed in the corresponding zone is adjusted using the controller 1000 in S500. For example, as shown in FIG. 3, when the contaminant 603 has formed inside the pipe 900 in the fourth zone (Z4 of FIG. 4), the controller 1000 controls the fourth heater (H4 of FIG. 4) disposed on the outside of the pipe 900 in the fourth zone Z4. For example, the fourth heater H4 may operate more strongly than before.

Next, whether the temperature is normal is checked in S600. Specifically, whether the temperature is normal is checked using the temperature sensor disposed on the outside of the pipe 900 in each zone. For example, when it is determined that the contaminant 603 has formed in the fourth zone Z4, the fourth temperature sensor (304 of FIG. 3) disposed on the outside of the pipe 900 in the fourth zone Z4 is used to check whether the internal temperature of the pipe 900 in the fourth zone Z4 is normal. When the temperature is normal and the contaminant 630 has removed, the apparatus operates normally in S700.

When the temperature inside the pipe 900 in each zone is not normal, the process of comparing the amplitudes of the ultrasonic wave and the reflected wave in each zone obtained using the ultrasonic sensor with each other and determining whether the zone is the abnormal zone based on the comparing result is repeated in S300. For example, when it is determined that the temperature inside the pipe 900 in the fourth zone Z4 is not normal such that the contaminant 630 has not removed, the fourth ultrasonic wave (U41 in FIG. 3) and the fourth reflected wave (U42 in FIG. 3) are detected in the fourth zone Z4, and the amplitudes thereof are compared with each other, and whether the fourth zone Z4 is the abnormal zone is determined based on the comparing result. In FIG. 12, each step is illustrated as being performed once. However, this is only for convenience of description and the present disclosure is not limited thereto. Each process may be repeated multiple times.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A substrate treating apparatus comprising:
a pipe including a first zone and a second zone, and configured to provide a precursor;
a first heater disposed to surround an outside of the pipe in the first zone and configured to provide heat to an inside of the pipe in the first zone;
a first ultrasonic sensor disposed on the outside of the pipe in the first zone, and configured to generate a first ultrasonic wave directed toward the inside of the pipe in the first zone and to receive a first reflected wave as the first ultrasonic wave reflected from the inside of the pipe in the first zone;
a second heater disposed to surround the outside of the pipe in the second zone and to provide heat into the inside of the pipe in the second zone;
a second ultrasonic sensor disposed on the outside of the pipe in the second zone, and configured to generate a second ultrasonic wave directed toward the inside of the pipe in the second zone and to receive a second reflected wave as the second ultrasonic wave reflected from the inside of the pipe in the second zone; and
a controller configured to:
determine whether a contaminant has formed inside the pipe in the first zone based on an analysis of the first reflected wave; and
determine whether a contaminant has formed inside the pipe in the second zone based on an analysis of the second reflected wave.

2. The substrate treating apparatus of claim 1, further comprising:
a first temperature sensor disposed on the outside of the pipe in the first zone and configured to detect a first temperature inside the pipe in the first zone; and
a second temperature sensor disposed on the outside of the pipe in the second zone and configured to detect a second temperature inside the pipe in the second zone,
wherein the controller is configured to further receive the first temperature from the first temperature sensor and the second temperature from the second temperature sensor.

3. The substrate treating apparatus of claim 2, wherein upon determination that the contaminant has formed inside the pipe in the first zone, the controller is configured to control the first heater to adjust the first temperature inside the pipe in the first zone to a sublimation point of the precursor,
wherein upon determination that the contaminant has formed inside the pipe in the second zone, the controller is configured to control the second heater to adjust the second temperature inside the pipe in the second zone to the sublimation point of the precursor.

4. The substrate treating apparatus of claim 2, wherein a first number of ultrasonic sensors and a second number of temperature sensors are disposed in the first zone,
wherein a third number of ultrasonic sensors and a fourth number of temperature sensors are disposed in the second zone,
wherein the first number and the third number are different from each other, and the second number and the fourth number are different from each other.

5. The substrate treating apparatus of claim 1, wherein the pipe further includes a third zone, wherein the first zone, the second zone, and the third zone are arranged in order,
wherein the substrate treating apparatus further comprises:
a third heater disposed to surround the outside of the pipe in the third zone and configured to provide heat to the inside of the pipe in the third zone; and
a third ultrasonic sensor disposed on the outside of the pipe in the third zone and configured to generate a third ultrasonic wave directed toward the inside of the pipe in the third zone, and to receive a third reflected wave as the third ultrasonic wave reflected from the inside of the pipe in the third zone,
wherein the controller is configured to receive the third reflected wave and to determine whether the contaminant has formed inside the pipe in the third zone based on an analysis of the third reflected wave.

6. The substrate treating apparatus of claim 5, wherein the controller is configured to:
compare amplitudes of the first, the second, and the third reflected wave with each other;
determine a zone where the contaminant has formed in a largest amount among the first zone, the second zone, and the third zone, based on a comparison of the amplitudes of the first, the second, and the third reflected wave; and
control a heater of the determined zone to adjust a temperature inside the pipe in the determined zone to a sublimation point of the precursor.

7. The substrate treating apparatus of claim 5, further including:
a central supply tank and a chamber, the pipe connected to the central supply tank at one end and to the chamber at an opposite end,
wherein the first zone is positioned closer to the central supply tank than the second zone,
wherein the third zone is positioned closer to the chamber than the second zone,
wherein a length of the second zone is smaller than a length of the first zone and is larger than a length of the third zone.

8. The substrate treating apparatus of claim 1, wherein the controller is configured to analyze an amplitude of the first reflected wave and determine whether the contaminant has formed inside the pipe in the first zone, based on analysis of the amplitude of the first reflected wave,
wherein the controller is configured to analyze an amplitude of the second reflected wave and determine whether the contaminant has formed inside the pipe in the second zone,
based on analysis of the amplitude of the second reflected wave.

9. The substrate treating apparatus of claim 1, wherein the precursor in a gaseous state is delivered through the pipe,
wherein the contaminant is formed via phase change of the precursor into a liquid or solid state.

10. A substrate treating apparatus comprising:
a central supply tank for providing precursor;
a pipe connected to the central supply tank and constructed to deliver the precursor;
a chamber connected to the central supply tank via the pipe and constructed to receive the precursor; and
a controller,
wherein the pipe includes a first zone and a second zone,
wherein a first heater is disposed to surround an outside of the pipe in the first zone and is configured to provide heat into an inside of the pipe in the first zone,
wherein a first ultrasonic sensor is disposed on the outside of the pipe in the first zone and configured to generate a first ultrasonic wave directed toward the inside of the pipe in the first zone and to receive a first reflected wave as the first ultrasonic wave reflected from the inside of the pipe in the first zone,
wherein a first temperature sensor is disposed on the outside of the pipe in the first zone and is configured to detect a temperature inside the pipe in the first zone,
wherein a second heater is disposed to surround the outside of the pipe in the second zone and is configured to provide heat into the inside of the pipe in the second zone,
wherein a second ultrasonic sensor is disposed on the outside of the pipe in the second zone and is configured to generate a second ultrasonic wave into the inside of the pipe in the second zone and to receive a second reflected wave as the second ultrasonic wave reflected from the inside of the pipe in the second zone,
wherein a second temperature sensor is disposed on the outside of the pipe in the second zone and is configured to detect a temperature inside the pipe in the second zone,
wherein the controller is configured to determine whether a contaminant has formed inside the pipe in the first zone based on an analysis of the first reflected wave,
wherein the controller is configured to determine whether a contaminant has formed inside the pipe in the second zone based on an analysis of the second reflected wave.

11. The substrate treating apparatus of claim 10, wherein an atomic layer deposition (ALD) process or a chemical vapor deposition (CVD) process is performed inside the chamber.

12. The substrate treating apparatus of claim 10, wherein when the contaminant has not formed inside the pipe in the first zone, the first reflected wave has a first amplitude,
wherein when the contaminant has formed inside the pipe in the first zone, the first reflected wave has a second amplitude smaller than the first amplitude,
wherein the controller is configured to compare a magnitude of the first amplitude and a magnitude of the second amplitude to determine whether the contaminant has formed inside the pipe in the first zone.

13. The substrate treating apparatus of claim 10, wherein upon determination that the contaminant has formed inside the pipe in the first zone, the controller is configured to control the first heater to adjust the temperature inside the pipe in the first zone to a sublimation point of the precursor,
wherein upon determination that the contaminant has formed inside the pipe in the second zone, the controller is configured to control the second heater to adjust the temperature inside the pipe in the second zone to the sublimation point of the precursor.

14. The substrate treating apparatus of claim 10,
wherein the first ultrasonic sensor includes a plurality of first ultrasonic sensors, the first temperature sensor includes a plurality of first temperature sensors, the second ultrasonic sensor includes a plurality of second ultrasonic sensors, the second temperature sensor includes a plurality of second temperature sensors, and
wherein a number of the first ultrasonic sensors and a number of the first temperature sensors are different from each other, or
wherein a number of the second ultrasonic sensors and a number of the second temperature sensors are different from each other.

15. The substrate treating apparatus of claim 10, wherein the first zone is positioned closer to the central supply tank than the second zone is,
wherein a length of the first zone is larger than a length of the second zone.

16. The substrate treating apparatus of claim 10, further comprising:
a tank pressure gauge for measuring a pressure inside the central supply tank;
a tank temperature sensor for measuring a temperature inside the central supply tank;
a chamber pressure gauge for measuring a pressure inside the chamber; and
a chamber temperature sensor for measuring a temperature inside the chamber.

17. The substrate treating apparatus of claim 10, wherein the pipe in the first zone has a bent shape, and the pipe in the second zone has a straight shape,
wherein the first ultrasonic sensor includes a plurality of first ultrasonic sensors.

18. The substrate treating apparatus of claim 10, wherein the precursor in a gaseous state is delivered through the pipe,
wherein the contaminant is formed via phase change of the precursor into a liquid or solid state.

19. A substrate treating apparatus comprising:
a central supply tank;
a pipe connected to the central supply tank, and including a plurality of zones, wherein the pipe is constructed to receive precursor in a gaseous state from the central supply tank and deliver the precursor;
a chamber connected to the central supply tank through the pipe, and configured to receive the precursor and to perform an atomic layer deposition (ALD) process or a chemical vapor deposition (CVD) process using the precursor; and
a controller configured to determine whether each of the zones of the pipe has been contaminated,
wherein each heater surrounds an outside of the pipe in each of the zones and provides heat to an inside of the pipe in each zone,
wherein each ultrasonic sensor is disposed on the outside of the pipe in each zone and is configured to generate an ultrasonic wave into the inside of the pipe in each zone and receive a reflected wave as the ultrasonic wave reflected from the inside of the pipe in each zone,
wherein each temperature sensor is disposed on the outside of the pipe in each zone and is configured to detect a temperature inside the pipe in each zone,
wherein the controller is configured to determine whether the contaminant has formed inside the pipe in each zone based on analysis of the reflected wave corresponding to each zone, and
wherein the contaminant is generated via phase change of the precursor into a liquid state or a solid state.

20. The substrate treating apparatus of claim 19, wherein when no contaminant has formed in one zone among the plurality of zones, the reflected wave corresponding thereto is a first reflected wave having a first amplitude,
wherein when the contaminant has formed in one zone among the plurality of zones, the reflected wave corresponding thereto is a second reflected wave having a second amplitude smaller than the first amplitude,
wherein the controller is configured to compare the first amplitude of the first reflected wave and the second amplitude of the second reflected wave with each other and to determine whether the contaminant has formed inside the pipe in one zone among the plurality of zones, based on comparing the first amplitude and the second amplitude.
